(19) United States
(12) Patent Application Publication
(10) Pub. No.: US 2024/0332911 A1
(43) Pub. Date: Oct. 3, 2024

(54) SEMICONDUCTOR LASER ELEMENT

(71) Applicant: NICHIA CORPORATION, Anan-shi, Tokushima (JP)

(72) Inventors: Yoshitaka NAKATSU, Tokushima-shi, Tokushima (JP); Kazutaka TSUKAYAMA, Tokushima-shi, Tokushima (JP)

(21) Appl. No.: 18/574,890

(22) PCT Filed: Jun. 27, 2022
(86) PCT No.: PCT/JP2022/025431

§ 371 Date: Dec. 28, 2023

(30) Foreign Application Priority Data
Jun. 29, 2021 (JP) 2021-107383

(51) Int. Cl. H01S 5/343; H01S 5/026; H01S 5/12; H01S 5/22; H01S 5/30

(52) U.S. Cl. CPC H01S 5/34333; H01S 5/026; H01S 5/1231; H01S 5/2218; H01S 5/3063; H01S 2301/04; H01S 2301/163

(57) ABSTRACT

A semiconductor laser element includes a nitride semiconductor layered body defining an optical waveguide, and including a first n-side nitride semiconductor layer having a periodic structure of a refractive index periodically changing along a resonance direction of the optical waveguide, a p-side nitride semiconductor layer, an active layer including one or more well lavers and barrier lavers, the one or more well layers including an n-side well layer located closest to the first n-side nitride semiconductor laver, and the one or more barrier layers including an n-side barrier layer disposed between the n-side well layer and the first n-side nitride semiconductor layer, and a second n-side nitride semiconductor layer disposed between the first n-side nitride semiconductor layer and the active layer. The second n-side nitride semiconductor layer includes In and Ga. A thickness of the second n-side nitride semiconductor layer is greater than a thickness of the n-side barrier layer.

### CROSS-REFERENCE TO RELATED APPLICATIONS

This is a U.S. national phase application of PCT/JP2022/025431, filed on Jun. 27, 2022, which claims priority to Japanese Patent Application No. 2021-107383, filed on Jun. 29, 2021. The entire disclosure of Japanese Patent Application No. 2021-107383 is hereby incorporated herein by reference.

### BACKGROUND

The present disclosure relates to a semiconductor laser element.

Nowadays, a semiconductor laser element including a nitride semiconductor can emit light in an ultraviolet region to a green region and is used for various applications such as an optical disk, a light source for a projector, a medical light source, and an on-vehicle headlight. In applications such as a light source for spectroscopy and visible light communication, a narrow spectral width of a wavelength or high controllability of a wavelength may be desired. Distributed feedback (DFB) laser elements are expected to be used for such applications. For example, International Patent Publication No. WO 2019/146321 discloses a DFB laser element including a diffraction grating.

### SUMMARY

In a semiconductor laser element including a nitride semiconductor, a DFB laser element provided with a diffraction grating tends to have a threshold current greater than a Fabry-Perot semiconductor laser element provided with no diffraction grating.

A semiconductor laser element according to one embodiment of the present disclosure includes a nitride semiconductor layered body including an optical waveguide, in which the nitride semiconductor layered body includes a first n-side nitride semiconductor layer having a periodic structure of a refractive index periodically changing along a resonance direction of the optical waveguide, a second n-side nitride semiconductor layer, an active layer including one or more well layers and one or more barrier layers, and a p-side nitride semiconductor layer in this order, the active layer includes an n-side well layer located closest to the second n-side nitride semiconductor layer among the one or more well layers and an n-side barrier layer located between the n-side well layer and the second n-side nitride semiconductor layer among the one or more barrier layers, the second n-side nitride semiconductor layer is a nitride semiconductor layer including In and Ga, and a thickness of the second n-side nitride semiconductor layer is greater than a thickness of the n-side barrier layer.

According to the one embodiment of the present disclosure described above, a threshold current can be reduced in a semiconductor laser element having a periodic structure.

### BRIEF DESCRIPTION OF DRAWINGS

FIG. 1 is a schematic top view illustrating a semiconductor laser element of an embodiment.

FIG. 2 is a cross-sectional view taken along line II-II in FIG. 1.

FIG. 3 is a cross-sectional view taken along line III-III in FIG. 1.

FIG. 4 is a graph showing the relationship between a thickness of a second n-side nitride semiconductor layer and a light intensity ratio Γ_{grating} of a portion coupled to a diffraction grating in a first calculation example.

FIG. 5 is a graph showing the relationship between the thickness of the second n-side nitride semiconductor layer and optical confinement Γ_{well} of a well layer in the first calculation example.

FIG. 6 is a graph showing the relationship between the thickness of the second n-side nitride semiconductor layer and the ratio Γₚ of light leaking to a p-side nitride semiconductor layer in the first calculation example.

FIG. 7 is a graph showing a result of calculating a normalized coupling coefficient kL in the first calculation example.

FIG. 8 is a graph showing I-L characteristics of semiconductor laser elements of a first example and a first comparative example.

FIG. 9 is a graph showing wavelength spectra of the semiconductor laser elements of the first example and the first comparative example.

FIG. 10 is a graph showing a side mode suppression ratio of the semiconductor laser element of the first example.

FIG. 11 is a graph showing I-L characteristics of semiconductor laser elements of a second example and a second comparative example.

FIG. 12 is a graph showing a wavelength spectrum of the semiconductor laser element of the second example.

FIG. 13 is a graph showing a wavelength spectrum of the semiconductor laser element of the second comparative example.

FIG. 14 is a graph showing a side mode suppression ratio of the semiconductor laser element of the second example.

FIG. 15 is a Z-contrast image of a part of the semiconductor laser element of the second example.

### DESCRIPTION OF EMBODIMENTS

An embodiment of the present invention is described below with reference to the drawings. In the drawings, the same elements are given the same reference signs.

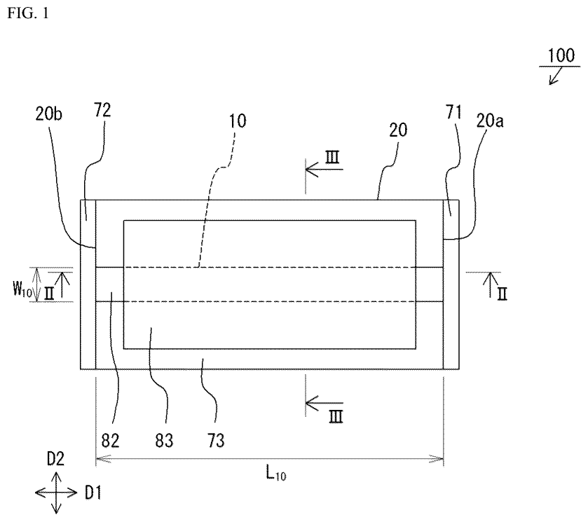

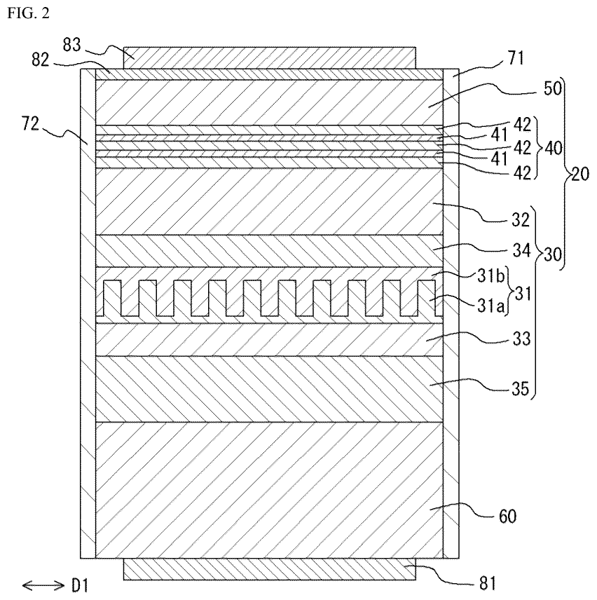

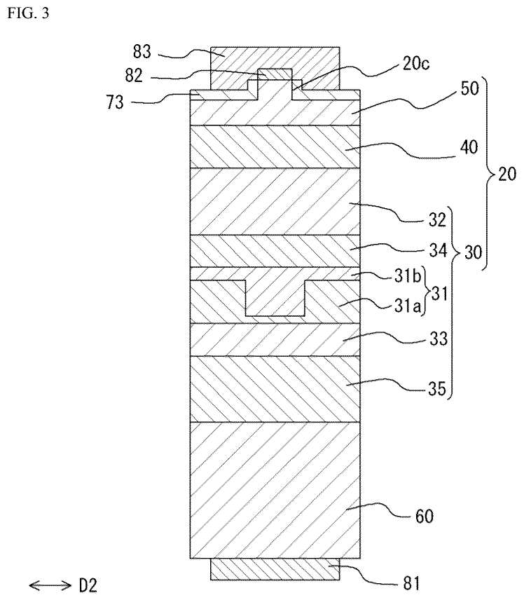

FIG. 1 is a schematic top view illustrating a semiconductor laser element of the present embodiment. FIG. 2 is a cross-sectional view taken along line II-II in FIG. 1. FIG. 3 is a cross-sectional view taken along line III-III in FIG. 1. As illustrated in FIGS. 1 to 3, a semiconductor laser element 100 of the present embodiment includes a nitride semiconductor layered body 20 including an optical waveguide 10. The semiconductor laser element 100 of the present embodiment includes a substrate 60, and the nitride semiconductor layered body 20 is disposed on the substrate 60. The nitride semiconductor layered body 20 includes an n-side nitride semiconductor layer 30, an active layer 40, and a p-side nitride semiconductor layer 50. In the present embodiment, a direction from the n-side nitride semiconductor layer 30 toward the p-side nitride semiconductor layer 50 is described as an upward direction. The upward direction may not necessarily coincide with an upward direction of a light emitting device or the like to which the semiconductor laser element 100 is fixed.

### Substrate 60

The substrate 60 is, for example, a semiconductor substrate. The substrate 60 is, for example, a nitride semiconductor substrate such as a GaN substrate. For example, a nitride semiconductor substrate may be used as the substrate 60, and an upper surface of the substrate 60 may be set as a +c plane (that is, a (0001) plane). In the present embodiment, a c plane is not limited to a plane exactly coinciding with a (0001) plane, but also includes a plane having an off angle in a range from ±0.03° to 1°. The semiconductor laser element 100 need not include the substrate 60. As the upper surface of the substrate, a nonpolar plane (M plane or A plane) or a semipolar plane having an off angle in a range from ±0.03° to 25° from the nonpolar plane may be used.

### Nitride Semiconductor Layered Body 20

The nitride semiconductor layered body 20 includes a plurality of nitride semiconductor layers. The nitride semiconductor constituting the nitride semiconductor layered body 20 is, for example, a group III nitride semiconductor. Examples of the group III nitride semiconductor include GaN, InGaN, AlGaN, InN, AlN, and InAlGaN. The nitride semiconductor layered body 20 includes the n-side nitride semiconductor layer 30, the active layer 40, and the p-side nitride semiconductor layer 50. The active layer 40 is disposed between the n-side nitride semiconductor layer 30 and the p-side nitride semiconductor layer 50. The n-side nitride semiconductor layer 30, the active layer 40, and the p-side nitride semiconductor layer 50 may be in direct contact with one another, or another semiconductor layer may be disposed between them. The nitride semiconductor layered body 20 includes a first n-side nitride semiconductor layer 31, a second n-side nitride semiconductor layer 32, the active layer 40, and the p-side nitride semiconductor layer 50 in this order. The nitride semiconductor layered body 20 is epitaxially grown on the substrate 60, for example. A main surface of the nitride semiconductor layered body 20 is, for example, a +c plane (that is, a (0001) plane).

In FIGS. 1 to 3, a resonance direction is defined as a direction D1, and a direction perpendicular to the resonance direction is defined as a direction D2. A width W₁₀ of the optical waveguide 10 in the direction (direction D2) perpendicular to the resonance direction is, for example, 1 μm or more. The width W₁₀ of the optical waveguide 10 is preferably 10 μm or more. Thus, the optical output of the semiconductor laser element 100 can be improved, and by providing the first n-side nitride semiconductor layer 31 having a periodic structure, a longitudinal mode of an oscillation wavelength can be unified or made close to unity. When a small amount of spontaneous emission light is taken into consideration, a state called a single longitudinal mode does not exist in a strict sense. Therefore, a case in which an output of a certain mode is sufficiently stronger than an output of another mode is referred to as a single longitudinal mode or a nearly single longitudinal mode. The width W₁₀ of the optical waveguide 10 is more preferably 50 μm or more and may be 80 μm or more. The width W₁₀ of the optical waveguide 10 can be set to 400 μm or less.

When the nitride semiconductor layered body 20 includes a ridge 20c as illustrated in FIGS. 1 to 3, a width of the ridge 20c may be regarded as the width W₁₀ of the optical waveguide 10. Alternatively, when the nitride semiconductor layered body 20 has a current confinement structure other than the ridge 20c, a width of the current confinement structure in the direction D2 may be regarded as the width W₁₀ of the optical waveguide 10.

A length L₁₀ of the optical waveguide 10 in the resonance direction (direction D1) may be, for example, 100 μm or more. As a distance from the active layer 40 to the periodic structure of the first n-side nitride semiconductor layer 31 increases, the coupling efficiency between light from the active layer 40 and the periodic structure decreases, but a decrease in the optical output of the semiconductor laser element 100 can be suppressed by increasing the length L₁₀ of the optical waveguide 10. Therefore, the length L₁₀ of the optical waveguide 10 is preferably 1000 μm or more. The length L₁₀ of the optical waveguide 10 may be 1500 μm or more. The length L₁₀ of the optical waveguide 10 can be set to 3000 μm or less. The length L₁₀ of the optical waveguide 10 is equal to a resonator length.

The nitride semiconductor layered body 20 includes a light emitting end surface 20a and a light reflecting end surface 20b. The light emitting end surface 20a and the light reflecting end surface 20b are surfaces that are not parallel to a main surface of the active layer 40. The light emitting end surface 20a and the light reflecting end surface 20b are, for example, surfaces perpendicular to the main surface of the active layer 40. The light emitting end surface 20a and the light reflecting end surface 20b are surfaces intersecting the resonance direction (direction D1) of the optical waveguide 10 and are, for example, surfaces perpendicular to the direction D1.

n-Side Nitride Semiconductor Layer 30

The n-side nitride semiconductor layer 30 includes one or more nitride semiconductor layers each containing an n-type impurity. Examples of the n-type impurity include Si and Ge. The n-side nitride semiconductor layer 30 may include an undoped layer that is not intentionally doped with impurities. The n-side nitride semiconductor layer 30 includes the first n-side nitride semiconductor layer 31 and the second n-side nitride semiconductor layer 32. The n-side nitride semiconductor layer 30 may include layers other than these layers. The semiconductor laser element 100 illustrated in FIGS. 1 to 3 includes a third n-side nitride semiconductor layer 33, a fourth n-side nitride semiconductor layer 34, and a fifth n-side nitride semiconductor layer 35. The n-side nitride semiconductor layer 30 may not include all these layers. The n-side nitride semiconductor layer 30 may include layers other than these layers.

Fifth n-Side Nitride Semiconductor Layer 35

The fifth n-side nitride semiconductor layer 35 is disposed on the opposite side of the first n-side nitride semiconductor layer 31 from the active layer 40. The fifth n-side nitride semiconductor layer 35 is disposed between the first n-side nitride semiconductor layer 31 and the substrate 60. The fifth n-side nitride semiconductor layer 35 is, for example, an n-side cladding layer. The fifth n-side nitride semiconductor layer 35 is, for example, a layer having the largest band gap energy in the n-side nitride semiconductor layer 30. The fifth n-side nitride semiconductor layer 35 is, for example, an AlGaN layer containing an n-type impurity.

Third n-Side Nitride Semiconductor Layer 33

The third n-side nitride semiconductor layer 33 is disposed between the fifth n-side nitride semiconductor layer 35 and the first n-side nitride semiconductor layer 31.

The third n-side nitride semiconductor layer 33 may have a refractive index between a refractive index of the fifth n-side nitride semiconductor layer 35 and an average refractive index of the first n-side nitride semiconductor layer 31. For example, in the first n-side nitride semiconductor layer 31, when the volume ratio of a first semiconductor portion 31a and a second semiconductor portion 31b is 1:1, the average refractive index of the first n-side nitride semiconductor layer 31 can be half the sum of a refractive index of the first semiconductor portion 31a and a refractive index of the second semiconductor portion 31b. Alternatively, when a refractive index of the third n-side nitride semiconductor layer 33 is lower than any one of the refractive index of the first semiconductor portion 31a and the refractive index of the second semiconductor portion 31b, it may be said that the refractive index of the third n-side nitride semiconductor layer 33 is lower than the average refractive index of the first n-side nitride semiconductor layer 31. The refractive index of each semiconductor can be inferred from the composition of the semiconductor.

By providing the third n-side nitride semiconductor layer 33, light leaking to the fifth n-side nitride semiconductor layer 35 and the substrate 60 can be reduced. For example, when the first n-side nitride semiconductor layer 31 has a periodic structure in which GaN and InGaN are periodically disposed, the refractive index of the first n-side nitride semiconductor layer 31 increases compared to a case in which the first n-side nitride semiconductor layer 31 has no periodic structure and is made of only GaN. When the refractive index of the first n-side nitride semiconductor layer 31 is relatively great in this way, the leakage of light is particularly preferably reduced by providing the third n-side nitride semiconductor layer 33.

The third n-side nitride semiconductor layer 33 is, for example, an AlGaN layer. The third n-side nitride semiconductor layer 33 may contain an n-type impurity. A thickness of the third n-side nitride semiconductor layer 33 may be in a range from 100 nm to 1000 nm.

First n-Side Nitride Semiconductor Layer 31

The first n-side nitride semiconductor layer 31 has a periodic structure in which the refractive index periodically changes along the resonance direction (direction D1) of the optical waveguide 10. In the nitride semiconductor, the activation rate of an n-type impurity (for example, Si) tends to be higher than the activation rate of a p-type impurity (for example, Mg). Therefore, the n-type impurity concentration of the n-side nitride semiconductor layer 30 can be made lower than the p-type impurity concentration of the p-side nitride semiconductor layer 50. The periodic structure is formed, for example, by forming a concavo-convex structure in one semiconductor layer and then filling the concavo-convex structure with another semiconductor layer, but the lower the impurity concentration, the more densely the concavo-convex structure is filled. Consequently, the periodic structure is suitably provided in the n-side nitride semiconductor layer 30. The periodic structure of the first n-side nitride semiconductor layer 31 has, for example, a refractive index greater than the refractive index of the fifth n-side nitride semiconductor layer 35. Alternatively, the first n-side nitride semiconductor layer 31 may also serve as an n-side cladding layer.

When the periodic structure is disposed close to the active layer 40, the electric field intensity of the p-side nitride semiconductor layer 50 becomes relatively high, which may cause an increase in absorption loss and/or a decrease in optical confinement in the active layer 40. Thus, the threshold current at which the semiconductor laser element 100 performs laser oscillation may increase. Therefore, the first n-side nitride semiconductor layer 31 having the periodic structure is provided at a position away from the active layer 40. For example, as illustrated in FIG. 2, the second n-side nitride semiconductor layer 32 is disposed between the first n-side nitride semiconductor layer 31 and the active layer 40. With this structure, the electric field intensity of the p-side nitride semiconductor layer 50 becomes relatively low, so that the absorption loss can be reduced and/or the optical confinement in the active layer 40 can be improved, and thus the threshold current of the semiconductor laser element 100 can be reduced. By reducing the threshold current, the current density at the time of laser oscillation can be reduced, and the probability that a high-order mode appears in the longitudinal mode can be reduced. Furthermore, the slope efficiency of the semiconductor laser element 100 can be improved by improving the optical confinement in the active layer 40. The calculation results are described below.

First, in a distributed feedback (DFB) laser or a distributed Bragg reflector (DBR) laser, a diffraction grating is formed along an optical waveguide and a forward wave and a backward wave are coupled to each other in the optical waveguide, so that feedback becomes strong in the vicinity of a Bragg frequency and frequency selectivity occurs. This enables laser oscillation in a single longitudinal mode or a nearly single longitudinal mode. For example, when light propagates parallel to the diffraction grating and Bragg reflection occurs, since the forward wave and the backward wave are to be in phase with each other, a diffraction grating period Λ is expressed by relationship (1) below by using a mode order m, an effective refractive index n_{eff}, and a wavelength λ.

$$Λ = m \frac{λ}{2 {n}_{eff}} \qquad ( 1 )$$

However, since the DFB mode changes depending on the phase of the diffraction grating when reflection occurs at an end face, a phase shift may be provided by changing the spacing of a part of the diffraction grating. For example, there are a λ/4 shift type, an equivalent phase shift type provided with a flat portion, a pitch modulation shift type in which a pitch period of a diffraction grating is changed, a multi-phase shift type, and the like. In addition, not only the case of having a one-dimensional periodic structure in a horizontal direction, but also the case of having a two-dimensional periodicity is conceivable. Even in the case of having a one-dimensional periodic structure, a structure having no periodicity or a structure in which the period is shifted in another in-plane direction with respect to the direction in which the periodic structure is formed is conceivable.

In the DFB laser, a coupling coefficient k indicates the degree of coupling per unit length when propagating light is diffracted by the diffraction grating, and a coupling coefficient k of a transverse electric (TE) mode with respect to a general shape is expressed by relationships (2) and (3) below.

$$k = \frac{{k}_{0}^{2}}{2 β {N}^{2}} \int Δ {n}^{2} ( x , z ) {E}_{y}^{2} ( x ) dx \qquad ( 2 )$$

$${N}^{2} = {\int }_{- ∞}^{∞} {E}_{y}^{2} ( x ) dx \qquad ( 3 )$$

Here, β is a propagation constant, E_{y} is an electric field of the TE mode, k₀=2π/λ, λ is a wavelength, and n(x, z) is a refractive index. For example, when the diffraction grating has a rectangular shape and is low in height and when the electric field intensity is considered to be constant in a region of the diffraction grating, the coupling coefficient k is approximately expressed by the following relationship (4).

$$k ≅ \frac{1}{λ} \times \frac{( {n}_{1}^{2} - {n}_{2}^{2} )}{{n}_{eff}} \times {Γ}_{grating} sin \frac{π {Λ}_{1}}{Λ} \qquad ( 4 )$$

Here, n₁ is a refractive index of a protruding portion of the diffraction grating, n₂ is a refractive index of a recessed portion of the diffraction grating, n_{eff} is an effective refractive index, Γ_{grating} is a light intensity ratio of a portion coupled to the diffraction grating, and Λ₁ is a width of the protruding portion of the diffraction grating. From these relationships above, it can be seen that the coupling coefficient increases as the refractive index difference between the recessed and protruding portions increases and the ratio of the electric field coupled to the diffraction grating increases.

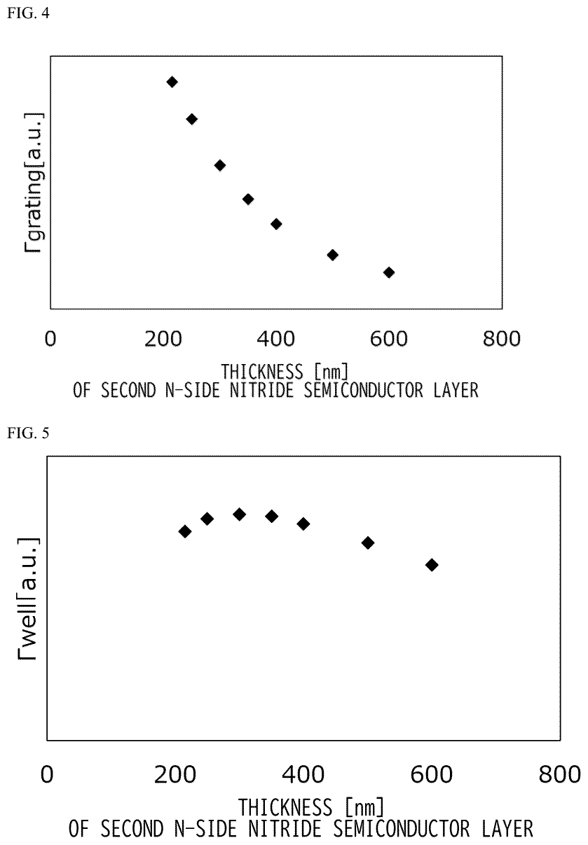

Γ_{grating} can be calculated by equivalent refractive index calculation. In the following calculation, the refractive index of each layer was calculated based on the composition ratio of a nitride semiconductor constituting the layer by using a relationship described in M. J. Bergmann, et. Al., JOURNAL OF APPLIED PHYSICS vol. 84 (1998) pp. 1196 to 1203. In a first calculation example, respective items illustrated in FIGS. 4 to 6 were calculated by using the same structure as that of the semiconductor laser element of a first example to be described below except that the thicknesses of the second n-side nitride semiconductor layer 32 (undoped In_{0.03}Ga_{0.97}N layer) were changed. The thicknesses of the second n-side nitride semiconductor layer 32 were 15 nm, 50 nm, 100 nm, 150 nm, 200 nm, 300 nm, and 400 nm. That is, in the first calculation example, the distances from the second n-side nitride semiconductor layer 32 to the active layer 40 were 215 nm, 250 nm, 300 nm, 350 nm, 400 nm, 500 nm, and 600 nm.

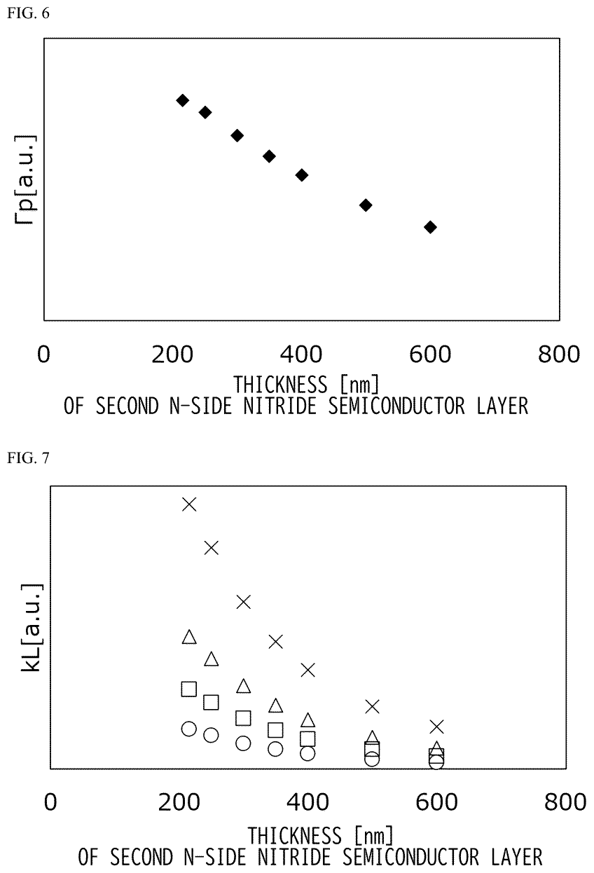

With respect to the first calculation example, FIGS. 4, 5, and 6 illustrate the relationship between the thicknesses of the second n-side nitride semiconductor layer 32 and the light intensity ratio Γ_{grating} of the portion coupled to the diffraction grating, the relationship between the thicknesses of the second n-side nitride semiconductor layer 32 and the optical confinement Γ_{well} of a well layer 41, and the relationship between the thicknesses of the second n-side nitride semiconductor layer 32 and the ratio Γₚ of light leaking to the p-side nitride semiconductor layer 50, respectively. As illustrated in FIG. 4, the thicker the second n-side nitride semiconductor layer 32 is, the more the light intensity in the diffraction grating decreases, and the degree of the decrease becomes gentle from about the thickness of 400 nm. As described above, since the coupling coefficient k is high when the ratio of the electric field coupled to the diffraction grating is high, it seems that the second n-side nitride semiconductor layer 32 is preferably thin. However, as illustrated in FIG. 5, the optical confinement Γ_{well} of the well layer 41 reaches a maximum at 300 nm and gently decreases before and after 300 nm. Similarly to a typical Fabry-Perot laser, the DFB laser has a greater threshold current when the optical confinement Γ in the active layer decreases. As illustrated in FIG. 6, the ratio Γₚ of light leaking to the p-side nitride semiconductor layer 50 increases as the second n-side nitride semiconductor layer 32 is made thinner. The increase in Γₚ causes an increase in free carrier absorption loss in the p-side nitride semiconductor layer 50 and loss inside the resonator increases, thereby causing an increase in threshold current and a decrease in slope efficiency.

For example, in the case of a p-type semiconductor layer, the free carrier absorption loss can be approximately explained by the product of leakage light Γₚ to the p-type semiconductor layer, an impurity concentration n of the p-type semiconductor layer, and a coefficient σ_{fc} reflecting a free carrier absorption cross-section are. This is indicated by relationship (5).

$${α}_{fc} = n \times {σ}_{fc} \times {Γ}_{p} \qquad ( 5 )$$

That is, even though the impurity concentration of the p-type semiconductor layer is the same, the free carrier absorption loss α_{fc} increases as the light leaking to the p-type semiconductor layer increases. Examples of the p-type semiconductor layer include a layer made of a nitride semiconductor containing a p-type impurity such as Mg. Since the activation rate of the p-type impurity in the nitride semiconductor is lower than the activation rate of an n-type impurity such as Si, a relatively large amount of p-type impurity is to be used in the p-type semiconductor layer, and free carrier absorption loss due to the p-type impurity increases. From the above relationship, it can be understood that as the light leaking to the p-side nitride semiconductor layer 50 increases, the free carrier absorption loss increases, and thus loss inside the resonator increases, resulting in an increase in the threshold current. Similarly, even though light leaking to the p-side nitride semiconductor layer 50 is the same, when the impurity concentration of the p-side nitride semiconductor layer 50 increases, the free carrier absorption loss α_{fc} increases and the loss inside the resonator increases, resulting in an increase in the threshold current.

From the calculation results of FIG. 6, the thickness of the second n-side nitride semiconductor layer 32 is preferably as great as possible in order to produce a DFB laser having low threshold current and high slope efficiency. On the other hand, in order to obtain a stable DFB laser with a single longitudinal mode or a nearly single longitudinal mode, the coupling coefficient k is important. From the calculation results of FIG. 4, the coupling coefficient k decreases as the thickness of the second n-side nitride semiconductor layer 32 increases. Therefore, when attention is paid only to the coupling coefficient k, it is conceivable that the greater the thickness of the second n-side nitride semiconductor layer 32 is, the more disadvantageous it is for obtaining a stable DFB laser with a single longitudinal mode or a nearly single longitudinal mode. However, a parameter that actually affects the coupling between the diffraction grating and propagating light is represented not only by the coupling coefficient k but also by the product KL of the coupling coefficient k and a region length L of the diffraction grating. KL is also referred to as a normalized coupling coefficient.

FIG. 7 shows the results of calculating the normalized coupling coefficient kL. In FIG. 7, the coupling coefficient k used in the calculation is the same as that in FIG. 4, and the region lengths L of ∘ (circle), □ (square), Δ (triangle), and x (cross) are 300 μm, 600 μm, 1000 μm, and 2000 μm, respectively. It can be seen from FIG. 7 that a desired normalized coupling coefficient kL can be obtained by adjusting the resonator length. That is, reducing the free carrier absorption loss by increasing the thickness of the second n-side nitride semiconductor layer 32 and obtaining a desired normalized coupling coefficient kL are compatible.

In the present embodiment, the periodic structure of the first n-side nitride semiconductor layer 31 is a diffraction grating. By providing the first n-side nitride semiconductor layer 31 having the periodic structure, the semiconductor laser element 100 can be used as a DFB laser element. The size of the periodic structure can be appropriately adjusted depending on the wavelength of laser light to be obtained, the composition of a semiconductor to be used, and the like.

The cross-sectional shape of the protrusion and recession constituting the periodic structure along the resonance direction (direction D1) of the optical waveguide 10 can be, for example, a sawtooth shape, a sinusoidal shape, a rectangular shape, a trapezoidal shape, an inverted trapezoidal shape, or the like. Although the cross-sectional shape of the protruding portion among the protrusion and recession constituting the periodic structure is a rectangular shape in FIG. 2, the cross-sectional shape is preferably a shape having an inclined side with a width becoming narrower toward the active layer 40, such as a trapezoidal shape. Thus, a semiconductor layer filling the protrusion and recession is easily grown, and the thickness of the semiconductor layer can be reduced. Each protruding portion of the protrusion and recession can have an upper surface. The upper surface is, for example, a surface parallel to the main surface of the active layer 40. Each recessed portion of the protrusion and recession illustrated in FIG. 2 has a bottom surface. The bottom surface is, for example, a surface parallel to the main surface of the active layer 40. Each recessed portion of the protrusion and recession may have a shape without a bottom surface such as a V-shape, for example.

The period (pitch) of the protrusion and recession constituting the periodic structure can be determined by a wavelength to be oscillated and an effective refractive index. The pitch of the protrusion and recession (one period of the protrusion and recession) can be, for example, in a range from 40 nm to 140 nm. The width of the protruding portion and the width of the recessed portion in the direction along the resonance direction (direction D1) of the optical waveguide 10 may be the same as each other or different from each other. When a diffraction structure of a higher order mode is provided, the pitch can be in a range from 120 nm to 420 nm in the third order diffraction or a range from 400 nm to 2000 nm in the 10th order diffraction. One of the width of the protruding portion and the width of the recessed portion is preferably in a range of ½ to 2 of the width of the other of the width of the protruding portion and the width of the recessed portion. The number of recessed portions and the number of protruding portions of the protrusion and recession constituting the periodic structure may be the same as each other or different from each other. For example, when the periodic structure starts with the recessed portion and ends with the recessed portion from the light emitting end surface 20a to the light reflecting end surface 20b, the number of recessed portions is larger than the number of protruding portions by one. Although FIG. 2 schematically illustrates 11 recessed portions and 10 protruding portions, the number of recessed portions and the number of protruding portions are not limited thereto. For example, when the resonator length is 300 μm and the period is 110 nm, the number of periods of the protrusion and recession constituting the periodic structure is about 2727. In this case, the number of recessed portions and the number of protruding portions constituting the periodic structure of one semiconductor laser element 100 is 2727 or 2728, respectively.

The height of the protrusion and recession constituting the periodic structure can be set to 300 nm or less or may be 200 nm or less. Since Γ_{grating} is increased by increasing the height of the protrusion and recession, the coupling coefficient k can be increased. Therefore, the height of the protrusion and recession is preferably 50 nm or more. For example, in a cross section perpendicular to the main surface of the active layer 40 and parallel to the resonance direction of the optical waveguide 10, the height of the protrusion and recession constituting the periodic structure is the shortest distance between a line parallel to the main surface of the active layer 40 and passing through a portion of the protrusion and recession closest to the active layer 40 and a line parallel to the main surface of the active layer 40 and passing through a portion of the protrusion and recession farthest from the active layer 40. Such a cross section can be observed by, for example, a transmission electron microscope (TEM). The cross section may be observed by a scanning transmission electron microscope (STEM).

The protrusion and recession constituting the periodic structure may be formed continuously from the light emitting end surface 20a to the light reflecting end surface 20b. As illustrated in FIG. 2, no protrusion and recession may be formed in the vicinity of the light emitting end surface 20a and/or the light reflecting end surface 20b. When the periodic structure is formed continuously from the light emitting end surface 20a to the light reflecting end surface 20b, the region length L of the periodic structure is equal to the length L₁₀ of the optical waveguide 10. Alternatively, the region length L of the periodic structure may be less than the length L₁₀ of the optical waveguide 10. The region length L of the periodic structure can be set to 80% or more of the length L₁₀ of the optical waveguide 10 and is preferably 90% or more. The region length L of the periodic structure is preferably in a range from 200 μm to 3000 μm and more preferably in a range from 300 μm to 1500 μm. This makes it easy to obtain desired coupling efficiency. Both a region of a periodic structure layer with a diffraction grating and a region without the diffraction grating can also be provided. In this case, the region length L of the periodic structure can be set to 10% of the length L₁₀ of the optical waveguide 10 and is preferably 30% or more. In such a case, a remaining region can be made to serve as a gain region without the diffraction grating and/or can be made to serve as a phase shift region for shifting a phase by applying a bias. In addition, a region of a periodic structure layer with the diffraction grating and a region having a complicated function without the diffraction grating can also be provided. In this case, the region length L of the periodic structure can be set to 5% or more of the length L₁₀ of the optical waveguide 10 and is preferably 10% or more. In such a case, an optical amplifier (semiconductor optical amplifier (SOA)), an electro absorption modulator (EAM), a Mach-Zehnder type intensity modulator, or the like can be integrated in the element.

The first n-side nitride semiconductor layer 31 includes a plurality of first portions, and a plurality of second portions each having a refractive index greater than the refractive index of the first portion. The periodic structure is formed by alternately disposing the plurality of first portions and the plurality of second portions along the resonance direction.

In the first n-side nitride semiconductor layer 31 illustrated in FIGS. 1 to 3, the plurality of first portions are connected to one common portion, and the plurality of first portions and the one common portion constitute one first semiconductor portion 31a. Similarly, the plurality of second portions are connected to one common portion, and the plurality of second portions and the one common portion constitute one second semiconductor portion 31b. In other words, the first semiconductor portion 31a includes the plurality of first portions projecting upward from the one common portion, the second semiconductor portion 31b includes the plurality of second portions projecting downward from the one common portion, and the first portions and the second portions are alternately disposed along the direction D1. The composition of the common portion of the first semiconductor portion 31a is the same as the composition of the first portion. The composition of the common portion of the second semiconductor portion 31b is the same as the composition of the second portion. The expression “having the same composition” refers to being obtained by forming without intentionally making the composition different and may include an error caused in manufacturing. The first semiconductor portion 31a includes the plurality of first portions and the second semiconductor portion 31b includes the plurality of second portions in the above description: however, the first semiconductor portion 31a may include the plurality of second portions and the second semiconductor portion 31b may include the plurality of first portions.

The first semiconductor portion 31a can be obtained, for example, by forming a first semiconductor layer to be the first semiconductor portion 31a and then removing a part of the first semiconductor layer by dry etching or the like. When the first semiconductor layer is removed down to a lower surface during the partial removal, a first semiconductor portion including only the plurality of first portions with no common portion can be formed. When the removal is performed at a depth not reaching the lower surface of the first semiconductor layer in consideration of the accuracy of the removal depth, the first semiconductor portion 31a including the one common portion and the plurality of first portions can be formed.

The second semiconductor portion 31b can be obtained, for example, by forming the second semiconductor portion 31b on the first semiconductor portion 31a. The second semiconductor portion 31b is filled between the plurality of first portions of the first semiconductor portion 31a. The second semiconductor portion 31b can be formed, for example, under growth conditions that lateral growth is promoted more than the first semiconductor layer. When the second semiconductor portion 31b is formed in this manner, the lower the impurity concentration of the second semiconductor portion 31b is, the more the possibility of generating a gap between the second semiconductor portion 31b and the first semiconductor portion 31a can be reduced. Therefore, the n-type impurity concentration of the second semiconductor portion 31b is preferably 1×10²⁰/cm³ or less. The n-type impurity concentration of the first semiconductor portion 31a may be in a range from 1×10¹⁷/cm³ to 1×10²⁰/cm³ or may be below a detection limit. The n-type impurity concentration of the first semiconductor portion 31a may be higher than the n-type impurity concentration of the second semiconductor portion 31b. The concentration of an impurity other than the n-type impurity in the second semiconductor portion 31b may be below the detection limit. The second semiconductor portion 31b is preferably made of GaN, and this can reduce the possibility of generating a gap between the second semiconductor portion 31b and the first semiconductor portion 31a.

At least one of both ends of either the plurality of first portions or the plurality of second portions in the direction perpendicular to the resonance direction may be located inside the nitride semiconductor layered body 20. Both ends of either the plurality of first portions or the plurality of second portions may be referred to as both ends of the periodic structure. When the periodic structure is formed by using a method in which a formation area and an operation time are proportional to each other, such as electron beam lithography, the formation time of the periodic structure can be shortened by making the width of the periodic structure narrower than the width of the semiconductor laser element 100.

In FIGS. 2 and 3, the first semiconductor portion 31a has a plurality of recessed shapes recessed in a direction away from the active layer 40. Portions of the first semiconductor portion 31a that sandwich the plurality of corresponding recessed shapes along the resonance direction (direction D1) are one of the first portions or the second portions. The plurality of recessed shapes are filled with the second semiconductor portion 31b, and the portions filling the plurality of recessed shapes are the other of the first portions or the second portions. The first semiconductor portion 31a may have a plurality of protruding shapes protruding toward the active layer 40. In this case, the plurality of protruding shapes of the first semiconductor portion 31a are one of the first portions or the second portions, and portions of the second semiconductor portion 31b that sandwich the plurality of corresponding protruding shapes along the resonance direction (direction D1) are the other of the first portions or the second portions. By at least one of both ends of a portion of the recessed shape or the protruding shape of the first semiconductor portion 31a in the direction (direction D2) perpendicular to the resonance direction being located inside the nitride semiconductor layered body 20, it is thought that the recessed shape or the protruding shape is likely to be stably formed. This is because the strength of the first semiconductor portion 31a can be expected to be improved as the width of the recessed shape or the protruding shape in the direction D2 becomes narrower. Preferably, the recessed shape or the protruding shape is a shape in which both ends of the recessed shape or the protruding shape in the direction D2 are located inside the nitride semiconductor layered body 20. The width of the recessed shape or the protruding shape in the direction D2 is equal to or greater than the width W₁₀ of the optical waveguide 10 and may be greater than the width W₁₀ of the optical waveguide 10. The width of the recessed shape or the protruding shape in the direction D2 may be a value obtained by adding 5 μm or more on each side and 10 μm or more in total to the width W₁₀ of the optical waveguide 10. The width of the recessed shape or the protruding shape in the direction D2 may be narrower than a width of a pad electrode 83 in the direction D2. When the periodic structure is formed by using a method in which a formation area and an operation time are proportional to each other, such as electron beam lithography, forming the first semiconductor portion 31a having a plurality of recessed shapes can shorten the formation time of the periodic structure compared to forming the first semiconductor portion 31a having a plurality of protruding shapes. Furthermore, the strength of the first semiconductor portion 31a can be expected to be improved when forming the first semiconductor portion 31a having a plurality of recessed shapes compared to when forming the first semiconductor portion 31a having a plurality of protruding shapes.

For example, the first portion is made of a nitride semiconductor including Ga, and the second portion is made of a nitride semiconductor including In and Ga. For example, the first portion is made of GaN, and the second portion is made of In_{X}Ga_{1-X}N (0<X<1). The In composition ratio of the second portion can be set to 0.001≤ X≤0.1. In this case, an n-side cladding layer can be provided as a layer separate from the first n-side nitride semiconductor layer 31, and the first n-side nitride semiconductor layer 31 can be disposed between the n-side cladding layer and the active layer 40. Thus, the threshold current can be reduced, and the optical confinement can be improved. When the first portion is made of GaN, the first semiconductor portion 31a preferably includes a plurality of second portions and the second semiconductor portion 31b preferably includes a plurality of first portions. Thus, since the protrusion and recession of the first semiconductor portion 31a can be filled with the second semiconductor portion 31b, the probability of generating a gap between the first portion and the second portion can be reduced. In such a first semiconductor portion 31a and a second semiconductor portion 31b, for example, in a Z-contrast image (ZC image) obtained by the STEM as illustrated in FIG. 15 to be described below, a change in contrast is gentler at the bottom of the recessed portion of the first semiconductor portion 31a than at the lateral surface of the recessed portion of the first semiconductor portion 31a. Such a change in contrast can be confirmed by, for example, observing a cross section perpendicular to the main surface of the active layer 40 and along the resonance direction of the optical waveguide 10. The Z-contrast image is a contrast image based on atomic weight.

For example, the first portion is made of a nitride semiconductor including Al and Ga, and the second portion is made of a nitride semiconductor including Ga. For example, the first portion is made of Al_{Y}Ga_{1-Y}N (0<Y<1), and the second portion is made of GaN. The Al composition ratio of the first portion can be set to 0.001≤Y≤0.2. When at least a part of the first n-side nitride semiconductor layer 31 includes a nitride semiconductor including Al and Ga, the first n-side nitride semiconductor layer 31 may be a layer serving as an n-side cladding layer.

The periodic structure of the first n-side nitride semiconductor layer 31 has a refractive index that changes periodically along an extending direction of the ridge 20c. In the periodic structure, the refractive index changes periodically along a direction connecting the light emitting end surface 20a and the light reflecting end surface 20b in the shortest distance. The periodic structure is disposed at least directly below the ridge 20c.

The distance from the first n-side nitride semiconductor layer 31 to the well layer 41 is preferably greater than 300 nm. Thus, the threshold current of the semiconductor laser element 100 can be reduced. Furthermore, the slope efficiency of the semiconductor laser element 100 can be improved. When the distance from the first n-side nitride semiconductor layer 31 to the well layer 41 is 300 nm or less, the threshold current increases, and laser oscillation may not occur even when a current of 400 mA is injected, for example. The distance from the first n-side nitride semiconductor layer 31 to the well layer 41 can be set to 800 nm or less and is preferably set to 500 nm or less, for example. This makes it easy to obtain desired coupling efficiency. The distance from the first n-side nitride semiconductor layer 31 to the active layer 40 may also be set within these numerical ranges. The distance from the periodic structure of the first n-side nitride semiconductor layer 31 to the well layer 41 may also be set within these numerical ranges, and the distance from the periodic structure to the active layer 40 may also be set within these numerical ranges. The distance from the periodic structure of the first n-side nitride semiconductor layer 31 to the well layer 41 (n-side well layer) may also be in a range from 320 nm to 800 nm or may also be in a range from 400 nm to 800 nm.

The thickness of the first n-side nitride semiconductor layer 31 is preferably 50 nm or more, more preferably 100 nm or more. This makes it easy to form a periodic structure in the first n-side nitride semiconductor layer 31. The thickness of the first n-side nitride semiconductor layer 31 can be set to 1000 nm or less and may be 500 nm or less.

The thickness of the periodic structure, that is, the length of the periodic structure in a direction perpendicular to the main surface of the active layer 40 is equal to or less than the thickness of the first n-side nitride semiconductor layer 31. The difference between the thicknesses of the first n-side nitride semiconductor layer 31 and the thicknesses of the periodic structure can be set in a range from 0 nm to 1000 nm.

Fourth n-Side Nitride Semiconductor Layer 34

The fourth n-side nitride semiconductor layer 34 is disposed between the second n-side nitride semiconductor layer 32 and the first n-side nitride semiconductor layer 31. The refractive index of the fourth n-side nitride semiconductor layer 34 may be lower than the refractive index of the second n-side nitride semiconductor layer 32 and greater than the average refractive index of the first n-side nitride semiconductor layer 31. The average refractive index of the first n-side nitride semiconductor layer 31 may be calculated from the volume ratio of the plurality of semiconductor portions constituting the first n-side nitride semiconductor layer 31. Alternatively, when the refractive index of the fourth n-side nitride semiconductor layer 34 is greater than any of the refractive indexes of the plurality of semiconductor portions, it may be said that the refractive index of the fourth n-side nitride semiconductor layer 34 is greater than the average refractive index of the first n-side nitride semiconductor layer 31.

The optical confinement in the active layer 40 can be improved by providing the fourth n-side nitride semiconductor layer 34. For example, when the first n-side nitride semiconductor layer 31 has a periodic structure in which AlGaN and GaN are periodically disposed, the refractive index of the first n-side nitride semiconductor layer 31 is lowered compared to a case in which the first n-side nitride semiconductor layer 31 has no periodic structure and is made of only GaN. When the refractive index of the first n-side nitride semiconductor layer 31 is relatively low in this way, the optical confinement in the active layer 40 is preferably improved by particularly providing the fourth n-side nitride semiconductor layer 34. Alternatively, the fourth n-side nitride semiconductor layer 34 may not be provided, and instead, the thickness of the common portion of the second semiconductor portion 31b may be set to 50 nm or more. Thus, the optical confinement in the active layer 40 can be improved. The thickness of the common portion of the second semiconductor portion 31b may be 300 nm or less.

The fourth n-side nitride semiconductor layer 34 is, for example, an InGaN layer. The fourth n-side nitride semiconductor layer 34 may contain an n-type impurity. The thickness of the fourth n-side nitride semiconductor layer 34 may be in a range from 1 nm to 500 nm.

Second n-Side Nitride Semiconductor Layer 32

The second n-side nitride semiconductor layer 32 is disposed between the first n-side nitride semiconductor layer 31 and the active layer 40.

As the distance between the first n-side nitride semiconductor layer 31 having the periodic structure and the active layer 40 is reduced, the electric field intensity of the p-side nitride semiconductor layer 50 increases to increase the absorption loss, and/or the optical confinement in the active layer 40 is lowered. By providing the second n-side nitride semiconductor layer 32, the electric field intensity of the p-side nitride semiconductor layer 50 can be lowered to reduce the absorption loss, and/or the optical confinement to the active layer 40 can be improved. Consequently, the threshold current of the semiconductor laser element 100 can be reduced.

The second n-side nitride semiconductor layer 32 is preferably a nitride semiconductor layer including In and Ga. The thickness of the second n-side nitride semiconductor layer 32 is preferably greater than the thickness of an n-side barrier layer to be described below. With such a configuration, the absorption loss can be reduced and/or the optical confinement in the active layer 40 can be improved.

The refractive index of the second n-side nitride semiconductor layer 32 is preferably greater than the average refractive index of the first n-side nitride semiconductor layer 31. The thickness of the second n-side nitride semiconductor layer 32 is preferably greater than the thickness of the first n-side nitride semiconductor layer 31. With such a configuration, the absorption loss can be reduced and/or the optical confinement in the active layer 40 can be improved.

The average refractive index of the first n-side nitride semiconductor layer 31 may be calculated from the volume ratio of the plurality of semiconductor portions constituting the first n-side nitride semiconductor layer 31. Alternatively, when the refractive index of the second n-side nitride semiconductor layer 32 is greater than any of the refractive indexes of the plurality of semiconductor portions, it may be said that the refractive index of the second n-side nitride semiconductor layer 32 is greater than the average refractive index of the first n-side nitride semiconductor layer 31. The thickness of the second n-side nitride semiconductor layer 32 may be compared with the thickness of the periodic structure of the first n-side nitride semiconductor layer 31 instead of the thickness of the first n-side nitride semiconductor layer 31.

The refractive index of the second n-side nitride semiconductor layer 32 is preferably greater than the refractive index of the n-side barrier layer. The n-side barrier layer has a band gap energy greater than the band gap energy of a well layer in order to serve as a barrier layer, but such an n-side barrier layer tends to have a relatively low refractive index. Therefore, by providing the second n-side nitride semiconductor layer 32 having a refractive index greater than the refractive index of the n-side barrier layer, the absorption loss can be reduced and/or the optical confinement in the active layer 40 can be improved. When the n-side barrier layer includes a plurality of layers, the refractive index of the second n-side nitride semiconductor layer 32 is preferably greater than an average refractive index of the n-side barrier layer and may be greater than the refractive index of any of the plurality of layers constituting the n-side barrier layer.

The second n-side nitride semiconductor layer 32 is made of, for example, In_{Z}Ga_{1-Z}N (0<Z<1). The In composition ratio of the second n-side nitride semiconductor layer 32 can be set to 0.001≤Z≤0.2. The second n-side nitride semiconductor layer 32 may be a composition gradient layer. The second n-side nitride semiconductor layer 32 is, for example, made of InGaN as a whole, and can be a composition gradient layer in which the In composition ratio increases toward the active layer 40. Such a composition gradient layer may also be referred to as a nitride semiconductor layer including In and Ga. As the composition gradient layer, when the composition gradient layer is formed such that a portion farthest from the active layer 40 is made of GaN, a portion closest to the active layer 40 is made of InGaN, and the In composition ratio increases toward the active layer 40, the remaining portion of the composition gradient layer excluding the portion farthest from the active layer 40 may be the second n-side nitride semiconductor layer 32.

The thickness of the second n-side nitride semiconductor layer 32 can be set to 150 nm or more and is preferably 200 nm or more. Thus, the absorption loss can be reduced and/or the optical confinement in the active layer 40 can be improved. The thickness of the second n-side nitride semiconductor layer 32 may be greater than the thickness of the fourth n-side nitride semiconductor layer 34. The thickness of the second n-side nitride semiconductor layer 32 can be set to 500 nm or less. From the relationship among the light intensity in the diffraction grating, the optical confinement in the well layer 41, and light leaking to the p-side nitride semiconductor layer 50 illustrated in FIGS. 4, 5, and 6, respectively, the thickness of the second n-side nitride semiconductor layer 32 may be in a range from 170 nm to 500 nm, in a range from 230 nm to 500 nm, or in a range from 300 nm to 500 nm.

### Active Layer 40

The active layer 40 is disposed between the n-side nitride semiconductor layer 30 and the p-side nitride semiconductor layer 50. The active layer 40 can have a multiple quantum well structure or a single quantum well structure. The active layer 40 includes one or more well layers 41 and one or more barrier layers 42.

The active layer 40 includes an n-side well layer among the one or more well layers 41, which is located closest to the second n-side nitride semiconductor layer 32, and an n-side barrier layer among the one or more barrier layers 42, which is located between the n-side well layer and the second n-side nitride semiconductor layer 32.

When a plurality of semiconductor layers are present between the n-side well layer and the second n-side nitride semiconductor layer 32, the thickness of the second n-side nitride semiconductor layer 32 is preferably greater than the thickness of the thickest layer among the plurality of semiconductor layers. Thus, the absorption loss can be reduced and/or the optical confinement in the active layer 40 can be improved. Moreover, the thickness of the second n-side nitride semiconductor layer 32 is preferably greater than the total thickness of the plurality of semiconductor layers located between the n-side well layer and the second n-side nitride semiconductor layer 32. Thus, the absorption loss can be further reduced and/or the optical confinement in the active layer 40 can be further improved.

The active layer 40 can be formed with, for example, a composition in which light with a wavelength in a range from 400 nm to 600 nm can be emitted. The one or more well layers 41 are each made of, for example, InGaN. The In composition ratio of InGaN constituting the one or more well layers 41 can be set in a range from 0.05 to 0.50, for example. The In composition ratio of InGaN constituting the one or more well layers 41 may be 0.15 or more.

p-Side Nitride Semiconductor Layer 50

The p-side nitride semiconductor layer 50 includes one or more nitride semiconductor layers each containing a p-type impurity. Examples of the p-type impurity include Mg. The p-side nitride semiconductor layer 50 may include an undoped layer that is not intentionally doped with impurities. The p-side nitride semiconductor layer 50 can include a contact layer. The p-side nitride semiconductor layer 50 can include one or more of an optical guide layer, an electron blocking layer, and a cladding layer. The p-side nitride semiconductor layer 50 may include all of these layers or may include layers other than these layers.

In the nitride semiconductor, the activation rate of the p-type impurity is lower than the activation rate of the n-type impurity. Therefore, the p-type impurity concentration of the p-side nitride semiconductor layer 50 tends to be higher than the n-type impurity concentration of the n-side nitride semiconductor layer 30. For example, the maximum value of the p-type impurity concentration in the p-side nitride semiconductor layer 50 is higher than the maximum value of the n-type impurity concentration in the n-side nitride semiconductor layer 30.

### First Protective Film 71 and Second Protective Film 72

The semiconductor laser element 100 may include a first protective film 71 and a second protective film 72. The first protective film 71 is provided on the light emitting end surface 20a of the nitride semiconductor layered body 20. The second protective film 72 is provided on the light reflecting end surface 20b of the nitride semiconductor layered body 20. One or both of the first protective film 71 and the second protective film 72 need not be provided. The first protective film 71 and the second protective film 72 may each include one or more dielectric films.

The first protective film 71 may be an AR (antireflective) coat. In this case, the reflectance of the first protective film 71 is preferably 1% or less, more preferably 0.1% or less, and is set to 0.001% or more. However, the AR coating is suitable for the first protective film 71 when the gain inside the resonator is sufficiently high. When the gain of the resonator is not sufficiently high, the first protective film 71 having a higher reflectance is preferably provided. In order to suppress an increase in the threshold current, the reflectance of the first protective film 71 is preferably 0.1% or more, more preferably 5% or more. In the semiconductor laser element 100 that emits laser light with a peak wavelength equal to or greater than 420 nm and less than 500 nm, the gain inside the resonator can be increased, and the reflectance of the first protective film 71 is preferably 25% or less, more preferably 18% or less. Thus, the slope efficiency can be increased, and high output can be obtained.

When it is desired to further suppress an increase in the threshold current, the reflectance of the first protective film 71 may be 18% or more, more preferably 30% or more. The semiconductor laser element 100 that emits laser light with a peak wavelength of 500 nm or more tends to have a lower gain inside the resonator compared to a case in which the peak wavelength is less than 500 nm. Therefore, in the semiconductor laser element 100 that emits laser light with a peak wavelength of 500 nm or more, the reflectance of the first protective film 71 is preferably 30% or more and less than the reflectance of the second protective film 72. Thus, the threshold current can be reduced. When a periodic structure is provided in the nitride semiconductor layered body 20 and the longitudinal mode of an oscillation wavelength is unified or made close to unity by the periodic structure, a confinement factor related to the laser oscillation is reduced compared to a case in which no periodic structure is provided. As the reflectance of the first protective film 71 is increased, the confinement factor can be increased. The reflectance of the first protective film 71 may be 60% or more and may be 80% or more.

The reflectance of the second protective film 72 is higher than the reflectance of the first protective film 71. The reflectance of the second protective film 72 can be set to, for example, 95% or more and may be 98% or more. The reflectance of the second protective film 72 can be set to, for example, 100% or less. The reflectance of the second protective film 72 may be 100%. The reflectance of the first protective film 71 and the reflectance of the second protective film 72 refer to a reflectance at the peak wavelength of laser light emitted by the semiconductor laser element 100.

### Insulating Film 73

The semiconductor laser element 100 can include an insulating film 73 provided on a part of the surface of the p-side nitride semiconductor layer 50. The insulating film 73 is, for example, a single-layer film or a multilayer film of oxide or nitride of Si, Al, Zr, Ti, Nb, Ta, or the like.

n-Electrode 81, p-Electrode 82, and Pad Electrode 83

The semiconductor laser element 100 includes an n-electrode 81 and a p-electrode 82. The n-electrode 81 is provided on a lower surface of the substrate 60. The p-electrode 82 is provided in contact with a part of the p-side nitride semiconductor layer 50. The p-electrode 82 is provided in contact with an upper surface of the ridge 20c, for example. The semiconductor laser element 100 can include the pad electrode 83 provided on the p-electrode 82. The pad electrode 83 is provided in contact with the p-electrode 82. Examples of a material of each electrode include a single-layer film or a multilayer film of a metal such as Ni, Rh, Cr, Au, W, Pt, Ti, and Al, an alloy thereof, conductive oxide including at least one selected from Zn, In, and Sn. Examples of the conductive oxide include indium tin oxide (ITO), indium zinc oxide (IZO), gallium-doped zinc oxide (GZO). In the present description, a side on which the p-side nitride semiconductor layer 50 is located when viewed from the active layer 40 is defined as an upper side, and a side on which the n-side nitride semiconductor layer 30 is located when viewed from the active layer 40 is defined as a lower side.

### Semiconductor Laser Element 100

The semiconductor laser element 100 is, for example, a DFB laser element. The peak wavelength of laser light emitted by the semiconductor laser element 100 can be set in a range from 400 nm to 600 nm, for example. The peak wavelength of the laser light emitted by the semiconductor laser element 100 is, for example, 500 nm or more. The semiconductor laser element 100 including the first n-side nitride semiconductor layer 31 has a periodic structure and can emit laser light with a peak wavelength of 500 nm or more.

The spectral width of the laser light emitted by the semiconductor laser element 100 may be set to 10 μm or less, and for example, is 3 μm or less. The spectral width of the laser light emitted by the semiconductor laser element 100 is, for example, 1 fm or more, and may be 10 fm or more. Alternatively, when a spectral linewidth is equal to or less than a measurement resolution, it may be said that the wavelength may be a single wavelength. The measurement resolution is, for example, a picometer-order.

The side mode suppression ratio (SMSR) of the laser light emitted by the semiconductor laser element 100 is, for example, 10 dB or more. The side mode suppression ratio is an intensity ratio between a peak (main mode) having the largest spectral intensity and a peak (side mode) having the second largest spectral intensity. The lower the side mode suppression ratio is, the higher the monochromaticity of the spectrum of laser light to be emitted, that is, unity in the longitudinal mode. The side mode suppression ratio of the laser light emitted by the semiconductor laser element 100 may be, for example, 60 dB or less. Alternatively, when the SMSR is equal to or higher than a background level, it may be said that the longitudinal mode is single. The background level is, for example, about 20 dB to 40 dB.

### First Example

In a first example, the following semiconductor laser element was produced. An MOCVD apparatus was used to produce an epitaxial wafer to be the semiconductor laser element. As raw materials, trimethylgallium (TMG), triethylgallium (TEG), trimethylaluminum (TMA), trimethylindium (TMI), ammonia (NH₃), silane gas, and bis (cyclopentadienyl) magnesium (Cp₂Mg) were used as appropriate.

An Al_{0.016}Ga_{0.984}N layer containing Si was grown with a thickness of 1.8 μm on a c plane GaN substrate (substrate 60).

Subsequently, an Al_{0.08}Ga_{0.92}N layer containing Si was grown with a thickness of 200 nm.

Subsequently, an In_{0.04}Ga_{0.96}N layer containing Si was grown with a thickness of 150 nm.

Subsequently, an Al_{0.08}Ga_{0.92}N layer containing Si (first semiconductor layer to be the first semiconductor portion 31a) was grown with a thickness of 650 nm.

The epitaxial wafer on which the above layers were formed was taken out from the MOCVD apparatus, and a periodic concavo-convex shape (periodic structure) was formed by using an electron beam lithography apparatus, reactive ion etching (RIE), and sputtering. The depth of a recessed portion was 200 nm, the width of the recessed portion was 80 nm, and a diffraction grating period A (one period of protrusion and recession) was 110 nm.

After the concavo-convex shape is formed, a GaN layer containing Si (second semiconductor portion 31b) was grown with a thickness of 200 nm by the MOCVD apparatus. 200 nm is a thickness from the uppermost portion of the protrusion of the concavo-convex shape to an upper surface of the GaN layer containing Si (second semiconductor portion 31b).

Subsequently, an undoped In_{0.03}Ga_{0.97}N layer (second n-side nitride semiconductor layer 32) was grown with a thickness of 240 nm. From the Al_{0.016}Ga_{0.984}N layer containing Si to the In_{0.03}Ga_{0.97}N layer is the n-side nitride semiconductor layer 30.

Subsequently, the active layer 40, which includes an n-side barrier layer (barrier layer 42) composed of three layers of a Si-doped GaN layer with a thickness of 1 nm, a Si-doped In_{0.05}Ga_{0.95}N layer with a thickness of 8 nm, and a Si-doped GaN layer with a thickness of 1 nm, an undoped In_{0.25}Ga_{0.75}N layer (well layer 41) with a thickness of 2.1 nm, an undoped GaN layer (barrier layer 42) with a thickness of 2.9 nm, an undoped In_{0.25}Ga_{0.75}N layer (well layer 41) with a thickness of 2.1 nm, and an undoped GaN layer (barrier layer 42) with a thickness of 2.9 nm in this order, was grown. Subsequently, an undoped composition gradient layer was grown with a thickness of 150 nm. The composition gradient layer was grown with In_{0.05}Ga_{0.95}N at the start of growth and GaN at the end of growth and with the In composition substantially monotonically decreasing in 120 steps so that the composition gradient was substantially linear.

Subsequently, an Al_{0.10}Ga_{0.90}N layer and an Al_{0.16}Ga_{0.84}N layer containing Mg were grown with thicknesses of 3 nm and 7 nm, respectively.

Subsequently, an Al_{0.015}Ga_{0.985}N layer containing Mg was grown with a thickness of 450 nm.

Subsequently, a GaN layer containing Mg was grown with a thickness of 15 nm. From the undoped composition gradient layer to the GaN layer is the p-side nitride semiconductor layer 50.

Subsequently, the epitaxial wafer on which the above layers were formed was taken out from the MOCVD apparatus, and the ridge 20c, the p-electrode 82, the pad electrode 83, the n-electrode 81, and the like were formed by using photolithography, RIE, and sputtering. Subsequently, singulation was performed, and the first protective film 71 and the second protective film 72 were formed on end surfaces to obtain the semiconductor laser element. The reflectance of the first protective film 71 was 80%, and the reflectance of the second protective film 72 was 98%. The semiconductor laser element has a ridge width of 2 μm, a resonator length of 300 μm, and an element width of 200 μm.

### Second Example

As a semiconductor laser element of a second example, the following semiconductor laser element was produced. The semiconductor laser element of the second example is different from the semiconductor laser element of the first example mainly in that a layer forming a periodic concavo-convex shape (first semiconductor layer to be the first semiconductor portion 31a) is an InGaN layer and the ridge width is 15 μm.

An Al_{0.016}Ga_{0.984}N layer containing Si was grown with a thickness of 1.25 μm on the c plane GaN substrate (substrate 60).

Subsequently, an Al_{0.08}Ga_{0.92}N layer containing Si was grown with a thickness of 250 nm.

Subsequently, an In_{0.04}Ga_{0.96}N layer containing Si was grown with a thickness of 150 nm.

Subsequently, an Al_{0.08}Ga_{0.92}N layer containing Si (fifth n-side nitride semiconductor layer 35) was grown with a thickness of 650 nm.

Subsequently, a GaN layer containing Si (third n-side nitride semiconductor layer 33) was grown with a thickness of 100 nm.

Subsequently, an In_{0.03}Ga_{0.97}N layer containing Si (first semiconductor layer to be the first semiconductor portion 31a) was grown with a thickness of 200 nm.

The epitaxial wafer on which the above layers were formed was taken out from the MOCVD apparatus, and a periodic concavo-convex shape (periodic structure) was formed by using an electron beam lithography apparatus, reactive ion etching (RIE), and sputtering. The depth of a recessed portion was 150 nm, the width of the recessed portion was 50 nm, and a diffraction grating period A (one period of protrusion and recession) was 115 nm.

After the concavo-convex shape is formed, a GaN layer containing Si (second semiconductor portion 31b) was grown with a thickness of 100 nm by the MOCVD apparatus. 100 nm is a thickness from the uppermost portion of the protrusion of the concavo-convex shape to an upper surface of the GaN layer containing Si (second semiconductor portion 31b).

Subsequently, an undoped In_{0.03}Ga_{0.97}N layer (second n-side nitride semiconductor layer 32) was grown with a thickness of 230 nm.

Subsequently, the active layer 40, which includes an n-side barrier layer (barrier layer 42) composed of three layers of a Si-doped GaN layer with a thickness of 1 nm, a Si-doped In_{0.05}Ga_{0.95}N layer with a thickness of 44 nm, and a Si-doped GaN layer with a thickness of 1 nm, an undoped In_{0.25}Ga_{0.75}N layer (well layer 41) with a thickness of 2.1 nm, an undoped GaN layer (barrier layer 42) with a thickness of 3.3 nm, an undoped In_{0.25}Ga_{0.75}N layer (well layer 41) with a thickness of 2.1 nm, and an undoped GaN layer (barrier layer 42) with a thickness of 2.2 nm in this order, was grown. Subsequently, an undoped composition gradient layer was grown with a thickness of 180 nm. The composition gradient layer was grown with In_{0.05}Ga_{0.95}N at the start of growth and GaN at the end of growth and with the In composition substantially monotonically decreasing in 120 steps so that the composition gradient was substantially linear.

Subsequently, an undoped composition gradient layer was grown with a thickness of 150 nm. The composition gradient layer was grown with GaN at the start of growth and Al_{0.04}Ga_{0.96}N at the end of growth and with the Al composition substantially monotonically increasing in 70 steps so that the composition gradient is substantially linear.

Subsequently, an undoped Al_{0.04}Ga_{0.96}N layer was grown with a thickness of 200 nm. Subsequently, an Al_{0.10}Ga_{0.90}N layer and an Al_{0.19}Ga_{0.81}N layer containing Mg were grown with thicknesses of 3.9 nm and 7 nm, respectively.

Subsequently, an Al_{0.04}Ga_{0.96}N layer containing Mg was grown with a thickness of 100 nm.

Subsequently, a GaN layer containing Mg was grown with a thickness of 15 nm.

Subsequently, the epitaxial wafer on which the above layers were formed was taken out from the MOCVD apparatus, and the ridge 20c, the p-electrode 82, the pad electrode 83, the n-electrode 81, and the like were formed by using photolithography, RIE, and sputtering. Subsequently, singulation was performed, and the first protective film 71 and the second protective film 72 were formed on end surfaces to obtain the semiconductor laser element. The reflectance of the first protective film 71 was 90%, and the reflectance of the second protective film 72 was 98%. The semiconductor laser element has a ridge width of 15 μm, a resonator length of 300 μm, and an element width of 200 μm.

### First Comparative Example

As a semiconductor laser element of a first comparative example, a semiconductor laser element was produced with the same structure as that of the semiconductor laser element of the first example except that no protrusion and recession was formed in the Al_{0.08}Ga_{0.92}N layer (first semiconductor layer) containing Si.

### Second Comparative Example

As a semiconductor laser element of a second comparative example, a semiconductor laser element was produced with the same structure as that of the semiconductor laser element of the second example except that no protrusion and recession was formed in the In_{0.03}Ga_{0.97}N layer (first semiconductor layer) containing Si.

### Evaluation

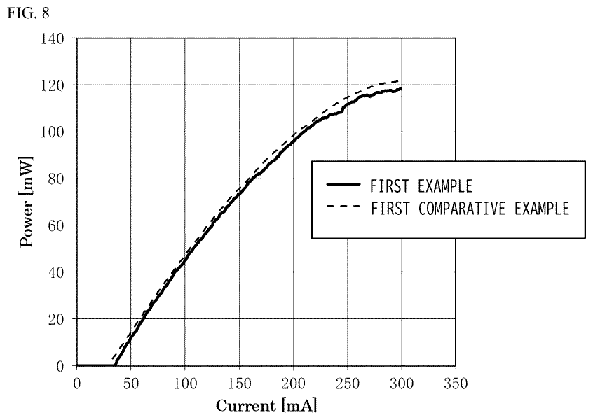

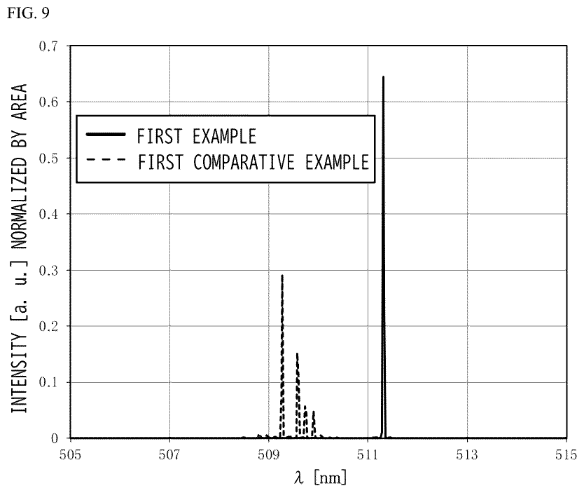

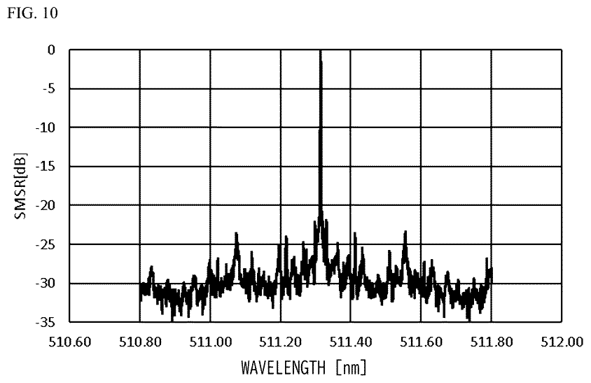

FIG. 8 shows the I-L characteristics of the semiconductor laser elements of the first example and the first comparative example. In FIG. 8, a horizontal axis represents current, and a vertical axis represents optical output. FIG. 9 shows the wavelength spectra of the semiconductor laser elements of the first example and the first comparative example. In FIG. 9, a horizontal axis represents a wavelength, and a vertical axis represents an intensity normalized by an area. FIG. 10 shows the side mode suppression ratio (SMSR) of the semiconductor laser element of the first example. The semiconductor laser element of the first example emitted laser light with a peak wavelength of about 512 nm. The side mode suppression ratio of the semiconductor laser element of the first example was 23.4 dB. The spectral width of the semiconductor laser element of the first example was 4 μm or less. The semiconductor laser element according to the first comparative example performed laser oscillation, but had many peaks of a wavelength spectrum, that is, performed laser oscillation in a longitudinal multimode.

The threshold current of the semiconductor laser element of the first example was 34 mA. The threshold current of the semiconductor laser element of the first comparative example was 28 mA. The difference in threshold current between the first example and the first comparative example was 6 mA, and it can be said that the semiconductor laser element of the first example was able to suppress an increase in the threshold current due to the provision of the periodic structure.

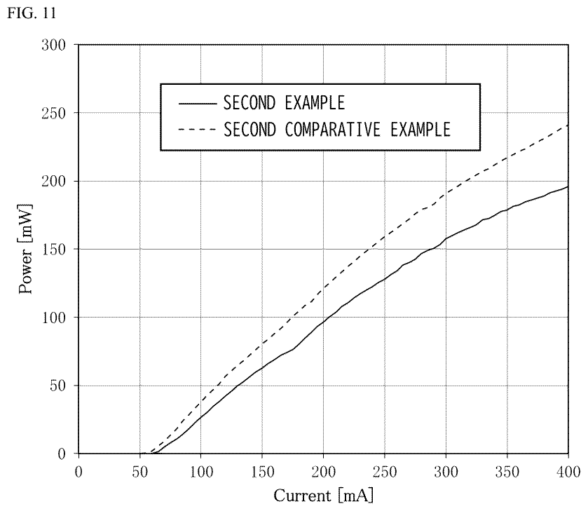

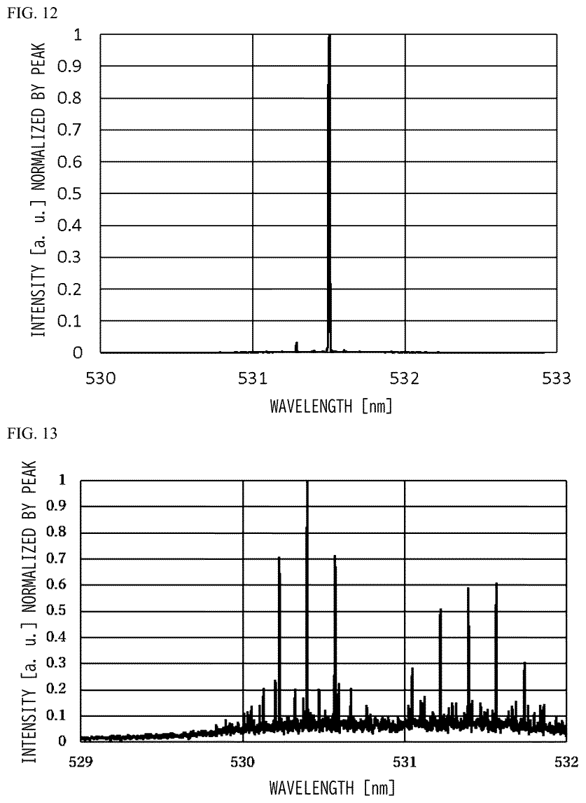

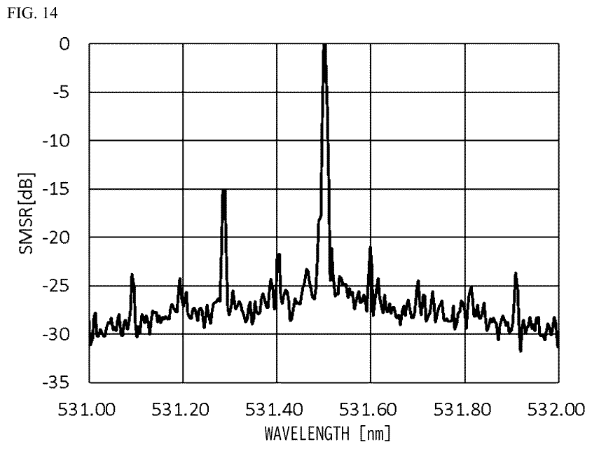

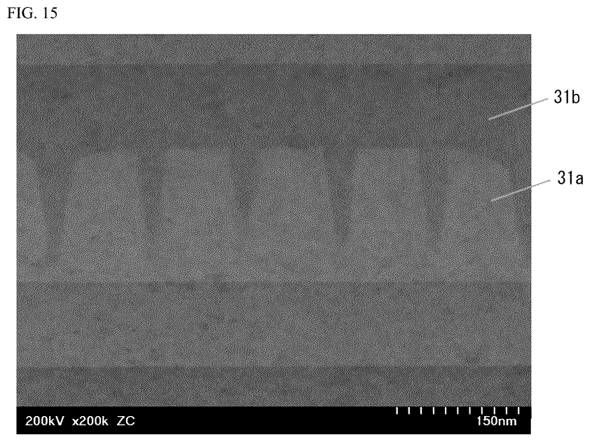

FIG. 11 shows the I-L characteristics of the semiconductor laser elements of the second example and the second comparative example. In FIG. 11, a horizontal axis represents current, and a vertical axis represents optical output. FIGS. 12 and 13 show the wavelength spectra of the semiconductor laser elements of the second example and the second comparative example, respectively. In FIGS. 12 and 13, a horizontal axis represents wavelength, and a vertical axis represents an intensity normalized by an area. FIG. 14 shows the side mode suppression ratio (SMSR) of the semiconductor laser element of the second example. The semiconductor laser element of the second example emitted laser light with a peak wavelength of about 532 nm. The side mode suppression ratio of the semiconductor laser element of the second example was 15 dB. The spectral width of the semiconductor laser element of the second example was 7 pm or less. The semiconductor laser element according to the second comparative example performed laser oscillation, but had many peaks of a wavelength spectrum, that is, performed laser oscillation in a longitudinal multimode.

The threshold current of the semiconductor laser element of the second example was 65 mA. The threshold current of the semiconductor laser element of the second comparative example was 60 mA. The difference in threshold current between the second example and the second comparative example was 5 mA, and it can be said that the semiconductor laser element of the second example was able to suppress an increase in threshold current due to the provision of the periodic structure.

FIG. 15 illustrates a Z-contrast image obtained by the STEM for a part of the semiconductor laser element of the second example. FIG. 15 is a Z-contrast image of a cross section of a portion including the first semiconductor portion 31a and the second semiconductor portion 31b. In the Z-contrast image, a difference in composition can be observed as a difference in display density in the image. In FIG. 15, the first semiconductor portion 31a and the second semiconductor portion 31b are illustrated with different display densities, and it can be seen that the first semiconductor portion 31a and the second semiconductor portion 31b have different compositions. It can be seen from FIG. 15 that a change in contrast from the first semiconductor portion 31a to the second semiconductor portion 31b is gentler at the bottom of the recessed portion of the first semiconductor portion 31a than at the lateral surface of the recessed portion of the first semiconductor portion 31a. Since the STEM also picks up information on the depth of a sample, a change in contrast at the boundary of a semiconductor layer or a semiconductor portion tends to be gentle, but the reason why the contrast is particularly gentle at the bottom of the recessed portion of the first semiconductor portion 31a is because the depth of the recessed portion may vary in a depth direction and the composition of the first semiconductor portion 31a may gradually change toward the composition of the second semiconductor portion 31b.

1. A semiconductor laser element comprising:
a nitride semiconductor layered body defining an optical waveguide, the nitride semiconductor layered body including
a first n-side nitride semiconductor layer having a periodic structure of a refractive index periodically changing along a resonance direction of the optical waveguide,
a p-side nitride semiconductor layer,
an active layer disposed between the first n-side nitride semiconductor layer and the p-side nitride semiconductor layer, and including one or more well layers and one or more barrier layers, the one or more well layers including an n-side well layer located closest to the first n-side nitride semiconductor layer among the one or more well layers, and the one or more barrier layers including an n-side barrier layer disposed between the n-side well layer and the first n-side nitride semiconductor layer, and
a second n-side nitride semiconductor layer disposed between the first n-side nitride semiconductor layer and the active layer, wherein
the second n-side nitride semiconductor layer includes In and Ga, and
a thickness of the second n-side nitride semiconductor layer is greater than a thickness of the n-side barrier layer.

2. The semiconductor laser element according to claim 1, wherein
a refractive index of the second n-side nitride semiconductor layer is greater than an average refractive index of the first n-side nitride semiconductor layer, and
the thickness of the second n-side nitride semiconductor layer is greater than a thickness of the first n-side nitride semiconductor layer.

3. The semiconductor laser element according to claim 1, wherein a refractive index of the second n-side nitride semiconductor layer is greater than a refractive index of the n-side barrier layer.

4. The semiconductor laser element according to claim 1, wherein the thickness of the second n-side nitride semiconductor layer is 200 nm or more.

5. The semiconductor laser element according to claim 1, wherein a distance from the first n-side nitride semiconductor layer to a closest one of the one or more well layers is greater than 300 nm.

6. The semiconductor laser element according to claim 1, wherein a thickness of the first n-side nitride semiconductor layer is 50 nm or more.

7. The semiconductor laser element according to claim 1, wherein at least one of both ends of the periodic structure in a width direction perpendicular to the resonance direction is located inside the nitride semiconductor layered body.

8. The semiconductor laser element according to claim 1, wherein
the first n-side nitride semiconductor layer includes a plurality of first portions and a plurality of second portions, the second portions each having a refractive index greater than a refractive index of each of the first portions, and
the periodic structure is formed by alternately disposing the first portions and the second portions along the resonance direction.

9. The semiconductor laser element according to claim 8, wherein
at least one of both ends of either the first portions or the second portions in a width direction perpendicular to the resonance direction is located inside the nitride semiconductor layered body.

10. The semiconductor laser element according to claim 8, wherein
each of the first portions is made of a nitride semiconductor including Ga, and
each of the second portions is made of a nitride semiconductor including In and Ga.

11. The semiconductor laser element according to claim 10, further comprising:
an n-side cladding layer disposed on an opposite side of the first n-side nitride semiconductor layer from the active layer; and
a third n-side nitride semiconductor layer disposed between the n-side cladding layer and the first n-side nitride semiconductor layer and having a refractive index between a refractive index of the n-side cladding layer and an average refractive index of the first n-side nitride semiconductor layer.

12. The semiconductor laser element according to claim 8, wherein
each of the first portions is made of a nitride semiconductor including Al and Ga, and
each of the second portions is made of a nitride semiconductor including Ga.

13. The semiconductor laser element according to claim 12, further comprising
a fourth n-side nitride semiconductor layer disposed between the second n-side nitride semiconductor layer and the first n-side nitride semiconductor layer, the fourth n-side nitride semiconductor layer having a refractive index lower than a refractive index of the second n-side nitride semiconductor layer and greater than an average refractive index of the first n-side nitride semiconductor layer.

14. The semiconductor laser element according to claim 13, wherein the thickness of the second n-side nitride semiconductor layer is greater than a thickness of the fourth n-side nitride semiconductor layer.

15. The semiconductor laser element according to claim 1, wherein a width of the optical waveguide in a direction perpendicular to the resonance direction is 10 μm or more.

16. The semiconductor laser element according to claim 1, wherein a length of the optical waveguide in the resonance direction is 1000 μm or more.

17. The semiconductor laser element according to claim 1, further comprising
a first protective film provided on a light emitting end surface of the nitride semiconductor layered body; and
a second protective film provided on a light reflecting end surface of the nitride semiconductor layered body, wherein
a reflectance of the first protective film is 30% or more, and
the reflectance of the first protective film is less than a reflectance of the second protective film.
